(19) United States
(12) Patent Application Publication
(10) Pub. No.: US 2018/0216220 A1
(43) Pub. Date: Aug. 2, 2018

(54) MASK

(71) Applicants: BOE TECHNOLOGY GROUP CO., LTD., Beijing (CN); ORDOS YUANSHENG OPTOELECTRONICS CO., LTD., Inner Mongolia (CN)

(72) Inventors: Shouhua LV, Beijing (CN); Pu SUN, Beijing (CN)

(21) Appl. No.: 15/544,915

(22) PCT Filed: Feb. 3, 2017
(86) PCT No.: PCT/CN2017/072806

§ 371 Date: Jul. 20, 2017

(30) Foreign Application Priority Data
May 9, 2016 (CN) 201620413388.2

(51) Int. Cl. C23C 14/04

(52) U.S. Cl. CPC C23C 14/042; H01L 51/56

(57) ABSTRACT

A mask includes a plurality of mask strips and a mounting frame, the plurality of mask strips are mounted on a mounting frame after being stretched. Each mask strip includes a plurality of mask units. Each mask unit includes an effective opening region and two vacant regions. Mask openings are disposed in the effective opening region. The two vacant regions are respectively provided on both sides of the effective opening region perpendicular to a stretching direction and close to the effective opening region. Vacant openings are disposed in the vacant regions. Wherein the contour shape of each mask opening is different from that of each vacant opening and the stress generated by the mask openings and the stress generated by the vacant openings in a stretching process can be mutually compensated.

### CROSS-REFERENCE TO RELATED APPLICATIONS

The present application is based on International Application No. PCT/CN2017/072806, filed on Feb. 3, 2017, which is based upon and claims priority to Chinese Patent Application No. 201620413388.2, filed on May 9, 2016, and the entire contents thereof are incorporated herein by reference.

### TECHNICAL FIELD

The present disclosure relates to the field of OLED display technology, and more particularly to a mask.

### BACKGROUND

An Organic Light-Emitting Diode (OLED) device has many advantages such as self-luminous, fast response time, wide viewing angle, low cost, simple manufacturing process, high resolution and high brightness. It is considered as an emerging application technology for next generation flat panel display.

According to the organic vapor deposition film technology for the OLED, a high precision mask is used as a mold, after volatilizing at high temperature, the organic material in molecular state is evaporated on the back glass through mask openings of an effective open region on the mask. Thus an organic light emitting layer for achieving organic light emission is formed. The mask typically includes a plurality of mask strips and a mounting frame. Specially, after each mask strip is stretched by a clamp to adjust its parameters to meet the requirements, the mask strip is affixed and secured to the surface of the mounting frame.

It has been found that the edge of the mask strip is downwardly curled during the adjustment of being stretched by the clamp. The greater the tensile strength, the more severe the curl deformation. In the vapor deposition process, a shadow effect will occur at the edge of the mask unit due to this kind of curling. That will eventually lead to poor color mixing at edges of the display panel in the vapor deposition process, thus the product yield is not high.

It should be noted that, information disclosed in the above background portion is provided only for better understanding of the background of the present disclosure, and thus it may contain information that does not form the prior art known by those ordinary skilled in the art.

### SUMMARY

In order to at least partly solve the technical problem existing in the related art, embodiments of the present disclosure provide a mask.

According to an embodiment of the present disclosure, there is provided a mask, including: a plurality of mask strips and a mounting frame, the plurality of mask strips being mounted on a mounting frame after being stretched, each mask strip comprising a plurality of mask units, each mask unit comprising an effective opening region and two vacant regions, mask openings being disposed in the effective opening region, the two vacant regions being respectively provided on both sides of the effective opening region perpendicular to a stretching direction and close to the effective opening region, vacant openings being disposed in the vacant regions, wherein contour shape of each mask opening is different from that of each vacant opening and stress generated by the mask openings and stress generated by the vacant openings in the stretching process can be mutually compensated.

is

### BRIEF DESCRIPTION OF THE DRAWINGS

The drawings are used to provide a further understanding of the disclosure and constitute a part of the specification, together with the following detailed description, for purposes of explanation of the disclosure, but are not to be construed as limiting the disclosure. In the drawings:

FIG. 1 is a schematic view of a mask strip in related art;

FIG. 1-1 is a schematic view of an example of mask units of a mask strip in FIG. 1;

FIG. 1-2 is a side view showing that curling occurs during the process of a mask strip composed of the mask units shown in FIG. 1-1 being stretched;

FIG. 2-1 is a schematic view of another example of mask units of a mask strip in FIG. 1;

FIG. 2-2 is a side view showing that no curling occurs during the process of a mask strip composed of the mask units shown in FIG. 2-1 being stretched;

FIG. 2-3 is a side view showing that curling occurs during the process of a mask strip composed of the mask units shown in FIG. 2-1 being stretched;

FIG. 3 is a schematic view of mask units of a mask strip provided by embodiments of the present disclosure; and

FIG. 4 is a schematic view of mask units of another mask strip provided by embodiments of the present disclosure.

### DETAILED DESCRIPTION

In order to provide a better understanding of the technical solution of the present disclosure by those skilled in the art, the mask provided by the present disclosure will be described in detail with reference to the accompanying drawings.

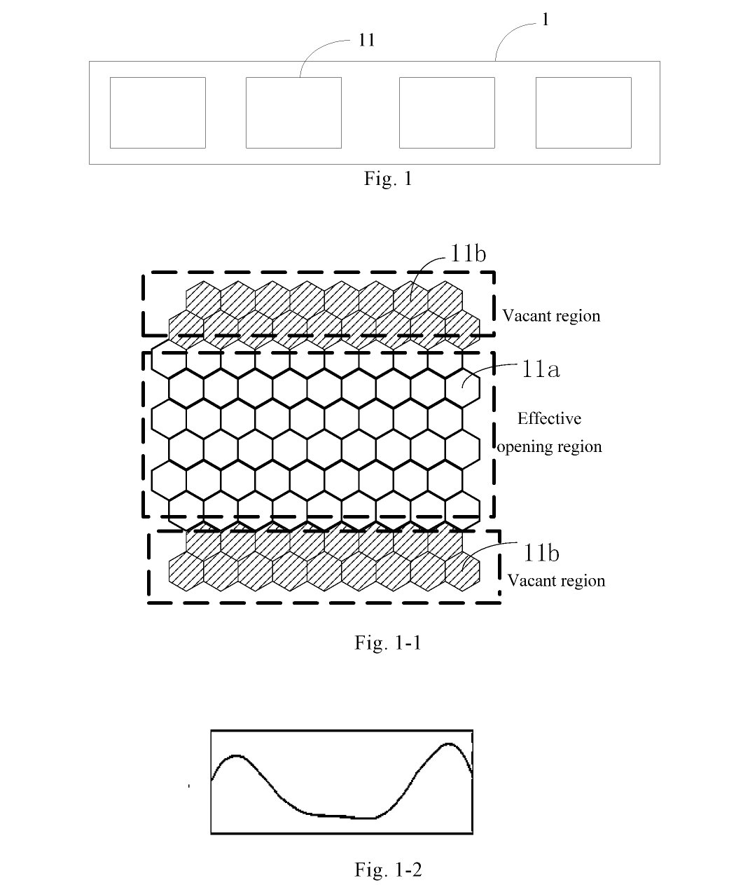

Referring to FIG. 1, each mask strip 1 is provided with a plurality of mask units (cells) 11. Referring to FIG. 1-1, each mask unit 11 includes an effective opening region 12 and two vacant regions 13 (which may be referred to as dummy regions). Mask openings 11a are provided in the effective opening region. The two vacant regions are respectively provided on both sides of the effective opening region perpendicular to a stretching direction and close to the effective opening region. The vacant region is provided with vacant openings 11b.

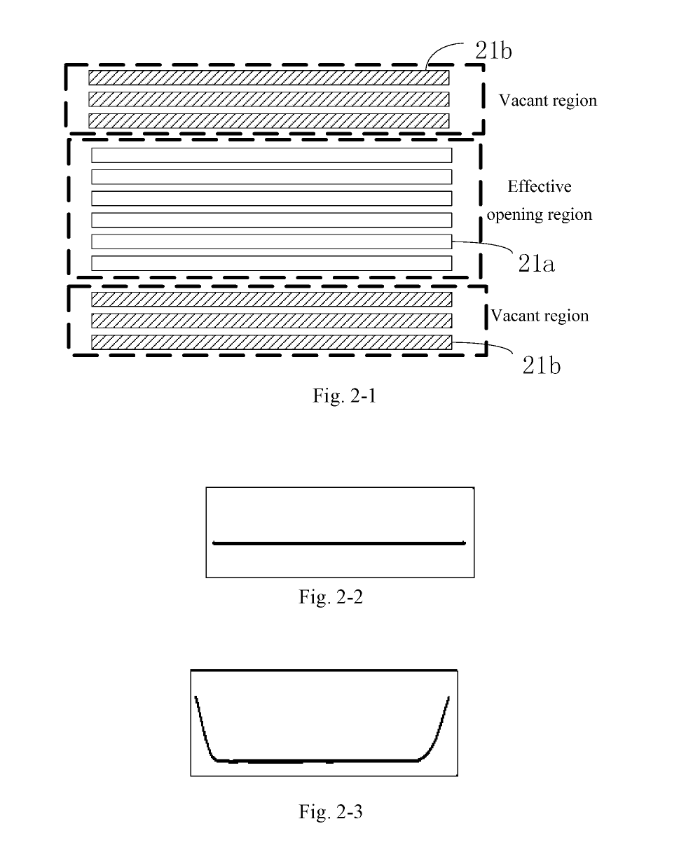

As shown in FIG. 1-1, there is shown a schematic view of a masking unit of masking strip in related art. The mask openings 11a in the effective opening region 12 and the vacant openings 11b in the vacant region 13 are porous (i.e., the mask strip is a slot-type mask strip). However, in the process of using a mask including a mask strip composed of the mask units shown in FIG. 1-1, it has been found that the edge of the mask strip is downwardly curled during the adjustment of being stretched by the clamp (as shown in FIG. 1-2). The greater the tensile strength, the more severe the curl deformation. In the vapor deposition process, a shadow effect will occur at the edge of the mask unit due to this kind of curling. That will eventually lead to poor color mixing at edges of the display panel in the vapor deposition process, thus the product yield is not high.

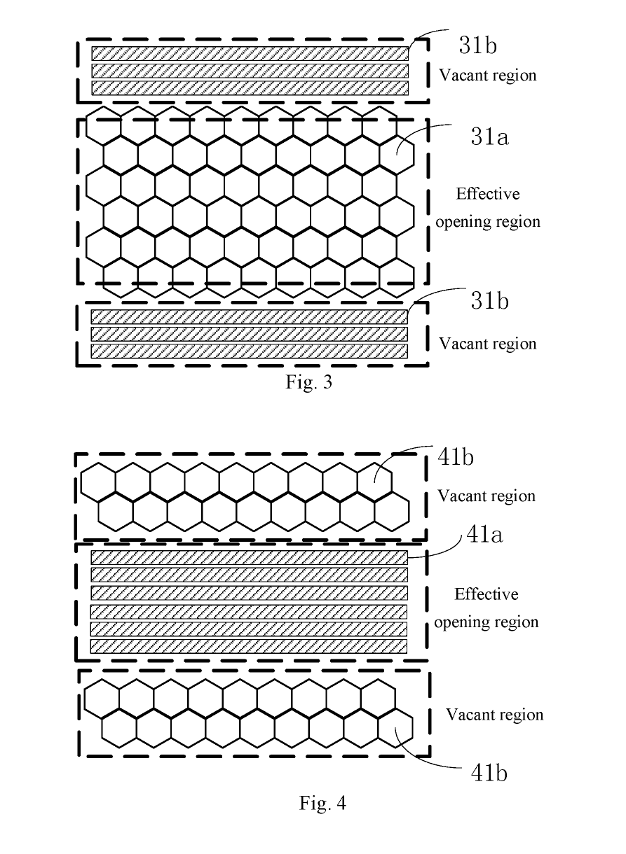

As shown in FIG. 2-1, there is shown a schematic view of another masking unit of masking strip in related art. The mask openings 21a in the effective opening region 22 and the vacant openings 21b in the vacant region 23 are thin strips (i.e., the mask strip is a slit-type mask strip). However, in the process of using a mask plate including a mask strip composed of the mask units shown in FIG. 2-1, it has been found that, during the adjustment of being stretched by the clamp, the mask strip will not be a large deformation if the tension of the mask strip is within a certain range (as shown in FIG. 2-2). The mask strip would be upwardly curled when the tension gradually increased beyond a certain range (as shown in FIG. 2-3). Similarly, in the vapor deposition process, a shadow effect will occur at the edge of the mask unit due to this kind of curling. That will eventually lead to poor color mixing at edges of the display panel in the vapor deposition process, thus the product yield is not high.

In order to at least partly solve the technical problem existing in the related art, the embodiment of the present disclosure provides a mask including a plurality of mask strips and a mounting frame, the plurality of mask strips are mounted on a mounting frame after being stretched. Each mask strip includes a plurality of mask units. Each mask unit includes an effective opening region and two vacant regions. Mask openings are disposed in the effective opening region. The two vacant regions are respectively provided on both sides of the effective opening region perpendicular to a stretching direction and close to the effective opening region. Vacant openings are disposed in the vacant regions. Wherein the contour shape of each mask opening is different from that of each vacant opening and the stress generated by the mask openings and the stress generated by the vacant openings in a stretching process can be mutually compensated.

According to the mask provided by the present disclosure, the contour shape of the mask opening is provided to be different from that of the vacant opening, so that the stress generated by the mask openings and the stress generated by the vacant openings in the stretching process can be mutually compensated. Therefore, curling of the mask strips in the stretching process can be prevented. The shadow effect at edges of the mask unit can be suppressed; thereby poor color mixing at edges of the display panel in the vapor deposition process can be avoided. The product yield can be improved.

The specific structure of the mask provided by the present disclosure will be described in detail below with reference to FIGS. 3 and 4.

As shown in FIG. 3, according to the mask units in an embodiment, the mask openings 31a in the effective opening region 32 are porous (a slot-type) and the vacant openings 31b in the vacant region 33 are thin strips (a slit-type). The lengthwise direction of the vacant openings 31b is substantially parallel to the direction of stretching, and in particular, when the stretching direction is the horizontal direction in FIG. 3, the lengthwise direction of the vacant openings 31b is substantially parallel to the horizontal direction.

Understandably, according to the mask strip formed by the mask units shown in FIG. 3, since the stress in the effective opening region 32 during the stretching adjustment is directed downward (i.e., perpendicular to the paper and inward the paper) and the stress in the vacant region 33 is directed upward (i.e., perpendicular to the paper and outward the paper), the ability of the mask strip to equalize the stress is enhanced, and the curling of the mask strips in the stretching process can be prevented.

Preferably, the lengthwise direction of the vacant opening 31b is parallel to the stretching direction. In FIG. 3, when the stretching direction is a horizontal direction, the lengthwise direction of the vacant opening 31b is also the horizontal direction.

As shown in FIG. 4, according to the mask units in another embodiment, the mask opening 41a in the effective opening region 42 is a thin strip (a slit-type) and the vacant opening 41b in the vacant region 43 is porous (a slot-type). The lengthwise direction of the mask opening 41a is substantially parallel to the direction of stretching, and in particular, when the stretching direction is the horizontal direction, the lengthwise direction of the mask opening 41a is substantially parallel to the horizontal direction.

Understandably, according to the mask strip formed by the mask units shown in FIG. 4, since the stress in the effective opening region 42 during the stretching adjustment is directed upward (i.e., perpendicular to the paper and outward the paper) and the stress in the vacant region 43 is directed downward (i.e., perpendicular to the paper and inward the paper), the ability of the barrier strip to equalize the stress is enhanced, and the curling of the mask strips in the stretching process can be prevented.

Preferably, the lengthwise direction of the mask opening 41a is parallel to the stretching direction, that is, the lengthwise direction is a horizontal direction.

According to the mask provided by embodiments of the present disclosure, the effective opening region may 42 be provided with a plurality of mask openings which are of the same shape and size and uniformly distributed. The vacant region may be provided with a plurality of vacant openings which are of the same shape and size and uniformly distributed, as shown in FIGS. 3 and 4.

Specifically, the mask strips can be fixed to the mounting frame by welding.

Each of the mask strips may be fixed in the horizontal direction on the mounting frame. A plurality of mask strips are arranged in close proximity to each other in a vertical direction. That is, each of the mask strips is fixed to the mounting frame in order from top to bottom.

Further, since the vapor deposition is often carried out in a high temperature and high pressure environment, in order to avoid serious deformation of the mask strips, the material of the mask strips needs to have advantages such as high-temperature and high-pressure resistant, small thermal expansion coefficient and morphological stability. In particular, the mask strips may be made of metal material. The metal material includes, but is not limited to, an invar alloy.

It should be noted that, FIGS. 3 and 4 show two specific implementations of the masking units of the mask strip provided by the present disclosure, but the present disclosure is not limited thereto. As long as the contour shape of the mask opening is different from that of the vacant opening and the stresses generated in the stretching process can be compensated for each other, such structures are also within the scope of the present disclosure.

It is to be understood that the above embodiments are merely illustrative embodiments for the purpose of illustrating the principles of the present disclosure, but the present disclosure is not limited thereto. It will be apparent to those skilled in the art that various changes and modifications can be made therein without departing from the spirit and essence of the present disclosure, which are also within the scope of the present disclosure.

1. A mask, comprising:
a plurality of mask strips and a mounting frame, the plurality of mask strips being mounted on the mounting frame after being stretched, each mask strip comprising a plurality of mask units, each mask unit comprising an effective opening region and two vacant regions, mask openings being disposed in the effective opening region, the two vacant regions being respectively provided on both sides of the effective opening region perpendicular to a stretching direction and close to the effective opening region, vacant openings being disposed in the vacant regions,
wherein a contour shape of each mask opening is different from that of each vacant opening and stress generated by the mask openings and stress generated by the vacant openings in a stretching process can be mutually compensated.

2. The mask of claim 1, wherein the contour shape of each mask opening is porous and the contour shape of each vacant opening is a thin strip, and a lengthwise direction of the vacant openings is substantially parallel to the stretching direction.

3. The mask of claim 1, wherein the contour shape of the mask opening is a thin strip and the contour shape of the vacant opening is porous, and a lengthwise direction of the mask openings is substantially parallel to the stretching direction.

4. The mask of claim 2, wherein the lengthwise direction of the vacant openings is parallel to the stretching direction.

5. The mask of claim 3, wherein the lengthwise direction of the mask openings is parallel to the stretching direction.

6. The mask of claim 1, wherein the effective opening region is provided with a plurality of mask openings, the mask openings are of the same shape and size and uniformly distributed, and
the vacant regions are provided with a plurality of vacant openings, the vacant openings are of the same shape and size and uniformly distributed.

7. The mask of claim 1, wherein the mask strips are fixed to the mounting frame by welding.

8. The mask of claim 1, wherein each of the mask strips is fixed on the mounting frame in a horizontal direction; and
the plurality of mask strips are arranged in close proximity to each other in a vertical direction.

9. The mask panel of claim 1, wherein the mask strips are made of metal material.

10. The mask panel of claim 9, wherein the metal material comprises an invar alloy.

11. The mask panel of claim 2, wherein the mask strips are made of metal material.

12. The mask panel of claim 3, wherein the mask strips are made of metal material.

13. The mask panel of claim 6, wherein the mask strips are made of metal material.

14. The mask panel of claim 7, wherein the mask strips are made of metal material.

15. The mask panel of claim 8, wherein the mask strips are made of metal material.

16. The mask panel of claim 10, wherein the metal material comprises an invar alloy.

17. The mask panel of claim 11, wherein the metal material comprises an invar alloy.

18. The mask panel of claim 12, wherein the metal material comprises an invar alloy.

19. The mask panel of claim 13, wherein the metal material comprises an invar alloy.

20. The mask panel of claim 14, wherein the metal material comprises an invar alloy.
